(19) United States
(12) Patent Application Publication
(10) Pub. No.: US 2016/0254031 A1
(43) Pub. Date: Sep. 1, 2016

(54) SEMICONDUCTOR MEMORY DEVICE

(71) Applicant: Kabushiki Kaisha Toshiba, Minato-ku (JP)

(72) Inventors: Kazuyuki NOGUCHI, Yokohama (JP); Yoshimichi SAKAI, Kawasaki (JP)

(73) Assignee: Kabushiki Kaisha Toshiba, Minato-ku (JP)

(21) Appl. No.: 14/842,028

(22) Filed: Sep. 1, 2015

Related U.S. Application Data
(60) Provisional application No. 62/121,132, filed on Feb. 26, 2015.

(51) Int. Cl. G11C 5/02; G11C 5/14; G11C 14/00

(52) U.S. Cl. CPC G11C 5/02; G11C 14/0018; G11C 5/14

(57) ABSTRACT

According to an embodiment of the present invention, a semiconductor memory device includes a substrate, a connector, a controller, a plurality of first capacitors, and a plurality of first memory packages. The connector is disposed at a first side of the substrate. The controller is mounted on a first face of the substrate and is disposed near the connector. The first capacitors are mounted on the first face of the substrate and are disposed along a second side opposing the first side. Each of the first memory packages includes a non-volatile semiconductor memory. The first memory packages are mounted on a second face of the substrate.

### CROSS-REFERENCE TO RELATED APPLICATIONS

This application is based upon and claims the benefit of priority from U.S. Provisional Application No. 62/121,132, filed on Feb. 26, 2015; the entire contents of which are incorporated herein by reference.

### FIELD

Embodiments described herein relate generally to semiconductor memory device including a non-volatile semiconductor memory.

### BACKGROUND

In a server used in a data center or the like, a memory device such as a solid state drive (SSD) is mounted. Such a memory device mounted in a server has a power loss protection (PLP) function. The PLP function is a function for storing information buffered in a buffer memory into a flash memory by using a backup internal power supply in a case where a sudden power shutdown occurs. As the backup internal power supply, a plurality of capacitors are mounted on a substrate.

### BRIEF DESCRIPTION OF THE DRAWINGS

FIG. 1 is a block diagram that illustrates a functional configuration of a semiconductor memory device;

FIG. 2 is a plan view that illustrates an external appearance of a semiconductor memory device;

FIG. 3A is a plan view that illustrates a substrate front face of a semiconductor memory device according to a first embodiment, and FIG. 3B is a plan view that illustrates a substrate rear face of the semiconductor memory device according to the first embodiment;

FIG. 4A is a plan view that illustrates a substrate front face of a semiconductor memory device according to a second embodiment, and FIG. 4B is a plan view that illustrates a substrate rear face of the semiconductor memory device according to the second embodiment;

FIG. 5A is a plan view that illustrates a substrate front face of a semiconductor memory device according to a third embodiment, and FIG. 5B is a plan view that illustrates a substrate rear face of the semiconductor memory device according to the third embodiment;

FIG. 6A is a plan view that illustrates a substrate front face of a semiconductor memory device according to a fourth embodiment, and FIG. 6B is a plan view that illustrates a substrate rear face of the semiconductor memory device according to the fourth embodiment;

FIG. 7A is a plan view that illustrates a substrate front face of a semiconductor memory device according to a fifth embodiment, and FIG. 7B is a plan view that illustrates a substrate rear face of the semiconductor memory device according to the fifth embodiment;

FIG. 8A is a plan view that illustrates a substrate front face of a semiconductor memory device according to a sixth embodiment, and FIG. 8B is a plan view that illustrates a substrate rear face of the semiconductor memory device according to the sixth embodiment;

FIG. 9A is a plan view that illustrates a substrate front face of a semiconductor memory device according to a seventh embodiment, and FIG. 9B is a plan view that illustrates a substrate rear face of the semiconductor memory device according to the seventh embodiment;

FIG. 10A is a plan view that illustrates a substrate front face of a semiconductor memory device according to an eighth embodiment, and FIG. 10B is a plan view that illustrates a substrate rear face of the semiconductor memory device according to the eighth embodiment; and

FIG. 11 is a diagram that illustrates an example of mounting of a semiconductor memory device.

### DETAILED DESCRIPTION

In general, according to one embodiment, a semiconductor memory device includes a substrate, a connector, a controller, a plurality of first capacitors, and a plurality of first memory packages. The connector is disposed at a first side of the substrate. The controller is mounted on a first face of the substrate and is disposed near the connector. The first capacitors are mounted on the first face of the substrate and are disposed along a second side opposing the first side. Each of the first memory packages includes a non-volatile semiconductor memory. The first memory packages are mounted on a second face of the substrate.

Semiconductor memory devices according to some embodiments of the present invention will be described below in detail with reference to the accompanying drawings. The present invention is not limited to the following embodiments.

### First Embodiment

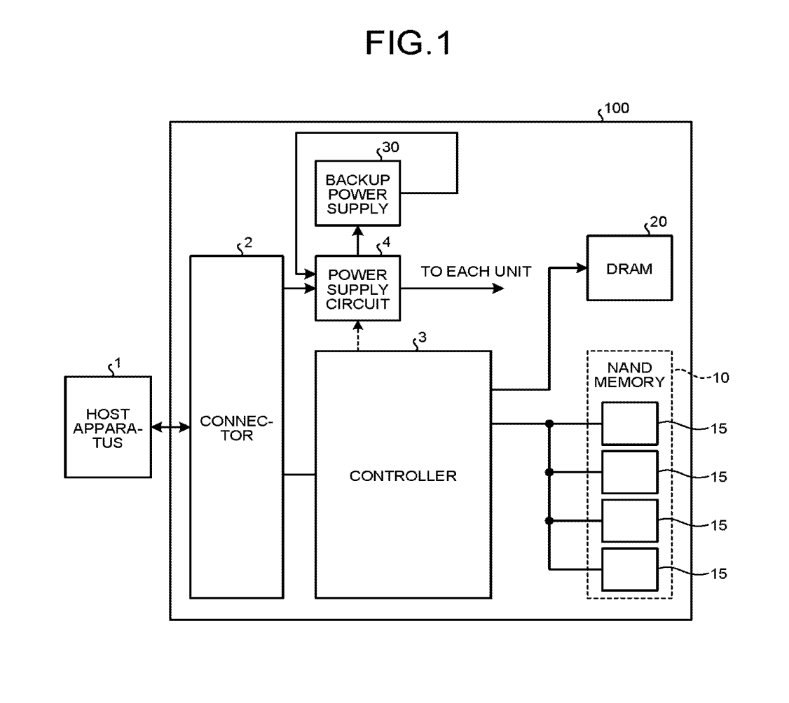

FIG. 1 is a diagram that illustrates an example of the configuration of a memory system 100 as a semiconductor memory device. This memory system 100, for example, is used for a server of a data center. The memory system 100 serves as an external memory device of a host apparatus 1 (hereinafter, abbreviated as a host). The host 1, for example, is a computer. The host 1 issues an access request (a write request, a read request, or the like) to the memory system 100. As an interface standard of a communication line between the host 1 and the memory system 100, an arbitrary standard may be adopted.

The memory system 100 includes a connector 2, a controller 3, a power supply circuit 4, a backup power supply 30, a NAND-type flash memory (hereinafter, it will be abbreviated as a NAND memory) 10 as a non-volatile memory, and a dynamic random access memory (DRAM) 20 as a volatile memory accessible at a speed higher than that of the NAND memory 10. The NAND memory 10 is used as a storage. In addition, the memory used as a storage is not limited to the NAND-type flash memory but may be a flash memory having a three-dimensional structure. Furthermore, for example, a NOR-type flash memory, a resistance random access memory (ReRAM), a magnetoresistive random access memory (MRAM), or the like can be used as the storage.

The memory system 100 is connected to the host 1 through the connector 2. As the interface standard of the connector 2, Serial ATA (SATA), PCIe (PCI Express), or the like is used.

The NAND memory 10 includes a plurality of memory packages 15. While four memory packages 15 are illustrated in FIG. 1, the number of memory packages 15 mounted in the memory system 100 may be two or more. One memory package 15 includes one or a plurality of memory chips. Each memory chip includes a memory cell array in which a plurality of memory cells is arranged in a matrix pattern. Each memory cell can store data of multiple levels. Each memory chip is configured by arranging a plurality of physical blocks that are units for data erasing. Each of the physical blocks is configured by a plurality of physical sectors. Data is written and is read for each physical sector. In one physical sector, in case of a two bit/cell writing system (four levels), for example, data corresponding to two pages is stored. On the other hand, in case of a one bit/cell writing system (two levels), for example, data corresponding to one page is stored in one physical sector.

The DRAM 20 includes areas serving as a write buffer and a read buffer used for transmitting data between the host 1 and the NAND memory 10. Write data received from the host 1 is temporarily stored in the DRAM 20 and, thereafter, is stored in the NAND memory 10. Data read from the NAND memory 10 is temporarily stored in the DRAM 20 and, thereafter, is transmitted to the host 1. The DRAM 20 is used also as a buffer into which firmware stored in the NAND memory 10 is loaded. The DRAM 20 is also used as a buffer into which management information stored in the NAND memory 10 is loaded. In the management information loaded into the DRAM 20, a logical/physical translation table, a block management table, and the like are included. In the logical/physical translation table, mapping between a logical address used by the host 1 and the physical address of the DRAM 20 or the physical address of the NAND memory 10 is registered. In the block management table, a use state (identification between an active block and a free block) of each physical block and the like are managed. The active block is a logical block in which valid data is recorded. The free block is a logical block, in which valid data is not recorded, that can be reused through an erasing process.

As the volatile memory, a static random access memory (SRAM) or a combination of a DRAM and an SRAM other than the DRAM 20 can be used. In addition, instead of the DRAM 20, an arbitrary memory having a speed higher than that of the NAND memory 10 can be used.

The controller 3 represents a controller package that controls the memory system 100. The controller 3 includes one or a plurality of CPUs (processors), a NAND controller that controls the NAND memory 10, a DRAM controller that controls the DRAM 20, a host interface that controls communication with the host 1 through the connector 2, an internal bus that connects these constituent elements, and the like. When a write command is received from the host 1 through the connector 2, the controller 3 writes write data into the NAND memory 10 through the DRAM 20 based on the above-described management information and the like stored in the DRAM 20. When a read command is received from the host 1 through the connector 2, the controller 3 reads data from the NAND memory 10 based on the management information and the like stored in the DRAM 20, and transmits the read data to the host 1 through the DRAM 20. In addition, the controller 3 controls an error correction process, compaction, wear leveling, and the like.

The power supply circuit 4 is connected to the host 1 through the connector 2 and receives power supply from the host 1. In addition, the power supply circuit 4 is connected to each circuit (the NAND memory 10, the DRAM 20, the backup power supply 30, and the controller 3) disposed inside the memory system 100. The power supply circuit 4 converts an external current power source supplied from the host 1 into a plurality of different internal DC power source voltages and supplies the converted internal DC power source voltages to circuits such as the NAND memory 10, the DRAM 20, the backup power supply 30, and the controller 3.

The backup power supply 30 includes a plurality of capacitors (condensers). The backup power supply 30 is charged through the supply of power from the host 1. The capacity of the backup power supply 30 is set in consideration of thermal deterioration of the memory system 100 during the warranty period thereof. In addition, the capacity of the backup power supply 30 is set in consideration of the operating time of a PLP function. The backup power supply 30 is capable of supplying power to the circuits (the NAND memory 10, the DRAM 20, the backup power supply 30, and the controller 3) disposed inside the memory system 100 through the power supply circuit 4. As a chip capacitor configuring the backup power supply 30, a conductive polymer tantalum solid electrolytic condenser, an electric double layer condenser (super capacitor), or the like can be used.

In a case where shutdown of the supply of power from the host 1 is detected, the controller 3 executes a PLP control process as below. The controller 3 switches the supply source of the internal power supply from the power supply circuit 4 (host 1) to the backup power supply 30. Accordingly, the power supplied from the backup power supply 30 is supplied to the circuits (the NAND memory 10, the DRAM 20, the backup power supply 30, and the controller 3) disposed inside the memory system 100. Next, the controller 3 stores the management information and information of user data and the like, which are stored in the DRAM 20, into the NAND memory 10 to make it to be non-volatile. When the PLP control process ends, the controller 3 shuts down the memory system 100.

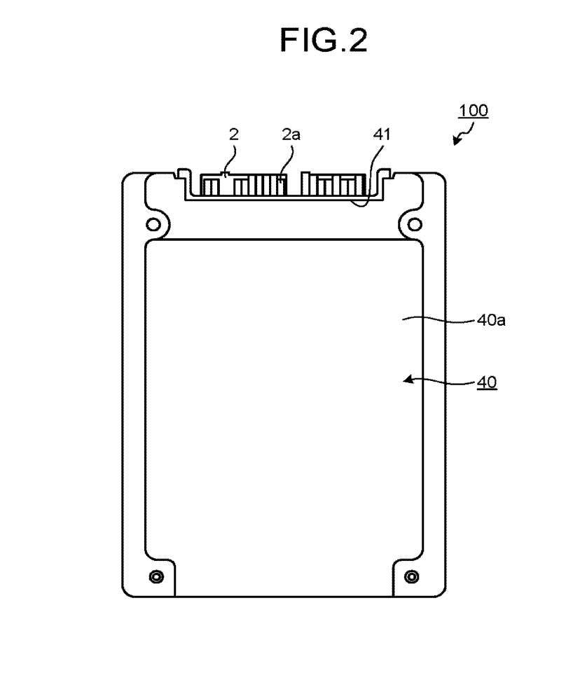

FIG. 2 is a plan view that illustrates an example of the external appearance of the memory system 100. The memory system 100 is housed inside a case (casing) 40. In one end portion of the case 40, a notched portion 41 is formed so as to expose the connector 2. The case 40 includes an upper case 40a and a lower case (not illustrated). The upper case 40a and the lower case are combined together using screws. This case 40 corresponds to a standard size of 1.8 inches. The height of the case 40 is 5 mm.

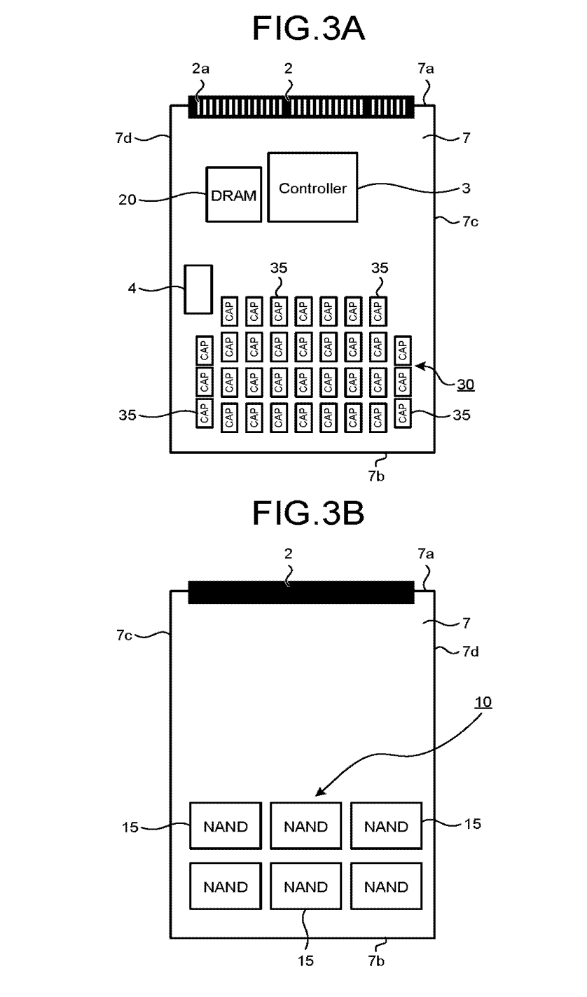

FIGS. 3A and 3B are plan views that illustrate an example of the arrangement of components of the memory system 100 according to a first embodiment. FIG. 3A illustrates the front face of a package substrate 7, and FIG. 3B illustrates the rear face of the package substrate 7. The package substrate (hereinafter, it will be abbreviated as a substrate) 7, for example, has a rectangular shape and has four sides 7a to 7d. At one shorter side 7a of the substrate 7, a connector 2 is disposed. The connector 2 is disposed such that a plurality of pins 2a (signal pins and a power supply pin) is exposed to the front (top) face side of the substrate 7.

As illustrated in FIG. 3A, on the front face side of the substrate 7, the controller 3, the DRAM 20, a plurality of chip capacitors (chip condensers) 35 configuring the backup power supply 30, and the power supply circuit 4 are mounted. As illustrated in FIG. 3B, on the rear face of the substrate 7, the plurality of the NAND packages 15 configuring the NAND memory 10 are mounted. In the case illustrated in FIG. 3B, six NAND packages 15 are mounted. In spaces in which nothing is illustrated on the front face and the rear face of the substrate 7, while other various circuits (e.g. an IC chip) are mounted, the circuits are not illustrated. The same applies to second and subsequent embodiments to be described below.

The controller 3 processes high-speed signals that are input or output through the connector 2 and thus, is disposed at a position located near the connector 2 among all the basic components. Here, for example, “being located near the connector 2” represents that a space between the connector 2 and the controller 3 is within 1 cm. The controller 3 is a heat generation source on the substrate 7.

The DRAM 20 is disposed adjacent to the controller 3. It is preferable that the DRAM 20 is adjacent to the controller 3 so as to be disposed between the controller 3 and a side 7d or a side 7c in terms of the layout of the components. However, the DRAM 20 may be configured to be disposed between the controller 3 and a side 7a or a side 7b.

The plurality of chip capacitors 35 are disposed along the side 7b in a concentrated manner and are disposed to be separate from the controller 3. In other words, the plurality of chip capacitors 35 are disposed in a concentrated manner at positions, which are disposed in a space between the side 7b and a center line of the sides 7a and 7b, located close to the side 7b as possibly as can. In this way, the thermal deterioration of the chip capacitors 35 can be configured to be minimal. In a case where this memory system 100 is housed in a case 40 having a size of 1.8 inches and a height of 5 mm, the height of each chip capacitor is preferably 2 mm or less.

It is preferable that the power supply circuit 4 is disposed near the backup power supply 30. In the case illustrated in FIG. 3A, the power supply circuit 4 is disposed between the backup power supply 30 and the side 7d. However, the power supply circuit 4 may be disposed at another position.

As illustrated in FIG. 3B, the NAND memory 10 is disposed along the side 7b in a concentrated manner on the rear face of the substrate 7. The NAND memory 10, similar to the backup power supply 30, is disposed to be separate from the controller 3. In the case illustrated in FIG. 3B, the NAND memory 10 is disposed in a concentrated manner at positions, which are located in a space between the side 7b and a center line of the sides 7a and 7b and located as closer to the side 7b as possible. In this way, the thermal influence on the NAND memory 10 can be configured to be minimal.

As described above, among the circuit components configuring the memory system 100, the controller 3 becomes a heat generation source on the substrate 7. Meanwhile, the chip capacitors 35 have a low degree of heat tolerance, and the capacity thereof decreases in accordance with thermal deterioration. In addition, the NAND memory 10 has a low degree of heat tolerance. Thus, in the case illustrated in FIGS. 3A and 3B, the plurality of chip capacitors 35 and the plurality of NAND packages 15 are disposed between the side 7b and the center line of the sides 7a and 7b, and the controller 3 is disposed between the side 7a and the center line of the sides 7a and 7b. In this way, according to the first embodiment, the plurality of chip capacitors 35 and the NAND memory 10 are disposed to be separate from the controller 3, and the adverse thermal influence of the controller 3 on the chip capacitors 35 and the NAND memory 10 can be minimized.

In addition, according to the first embodiment, it may be configured such that the plurality of NAND packages 15 are mounted on the front face of the substrate 7; and the controller 3, the DRAM 20, and the plurality of the chip capacitors 35 configuring the backup power supply 30, and the power supply circuit 4 are mounted on the rear face of the substrate 7.

### Second Embodiment

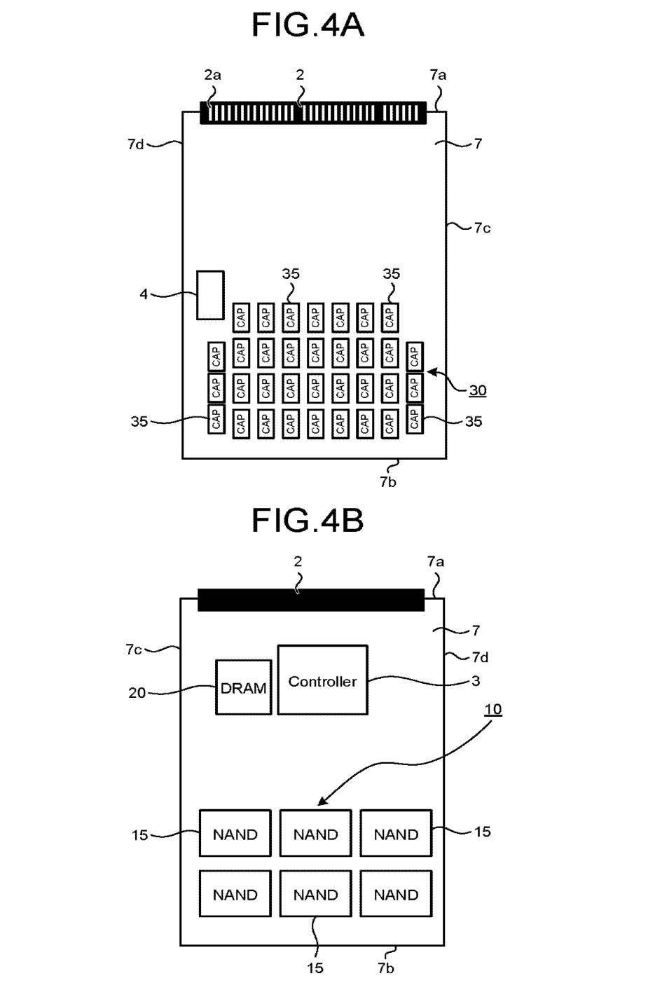

FIGS. 4A and 4B are plan views that illustrate an example of the arrangement of components of a memory system 100 according to a second embodiment. FIG. 4A illustrates the front face of a substrate 7, and FIG. 4B illustrates the rear face of the substrate 7. As illustrated in FIG. 4A, on the front face of the substrate 7, a plurality of chip capacitors 35 and a power supply circuit 4 are mounted. In addition, as illustrated in FIG. 4B, on the rear face of the substrate 7, a controller 3, a DRAM 20, and a plurality of NAND packages 15 configuring the NAND memory 10 are mounted.

As illustrated in FIG. 4B, the controller 3 is disposed on the rear face of the substrate 7 near the connector 2. The DRAM 20 is disposed between the controller 3 and a side 7c of the substrate 7 so as to be adjacent to the controller 3.

As illustrated in FIG. 4B, the NAND memory 10 is disposed along a side 7b in a concentrated manner on the rear face of the substrate 7. The NAND memory 10 is disposed to be separate from the controller 3. The NAND memory 10 is disposed in a concentrated manner at positions, which are located in a space between the side 7b and a center line of the sides 7a and 7b and located as closer to the side 7b as possible. In this way, the thermal influence on the NAND memory 10 can be configured to be minimal.

As illustrated in FIG. 4A, the plurality of chip capacitors 35 are mounted in a concentrated manner along the side 7b on the front face of the substrate 7 and are disposed to be separate from the controller 3. In other words, the plurality of chip capacitors 35 are disposed in a concentrated manner at positions, which are located in a space between the side 7b and a center line of the sides 7a and 7b and located as closer to the side 7b as possible. Accordingly, the thermal deterioration of the chip capacitors 35 can be configured to be minimal. The power supply circuit 4 is disposed near a backup power supply 30.

According to the second embodiment, the plurality of chip capacitors 35 and the plurality of NAND packages 15 are disposed between the side 7b and the center line of the sides 7a and 7b, and the controller 3 is disposed between the side 7a and the center line of the sides 7a and 7b. In this way, the plurality of chip capacitors 35 and the NAND memory 10 are disposed to be separate from the controller 3, and the adverse thermal influence of the controller 3 on the chip capacitors 35 and the NAND memory 10 can be minimized.

In addition, in the second embodiment, it may be configured such that the controller 3, the DRAM 20, and the plurality of NAND packages 15 are disposed on the front face of the substrate 7, and the backup power supply 30 and the power supply circuit 4 are disposed on the rear face of the substrate 7.

### Third Embodiment

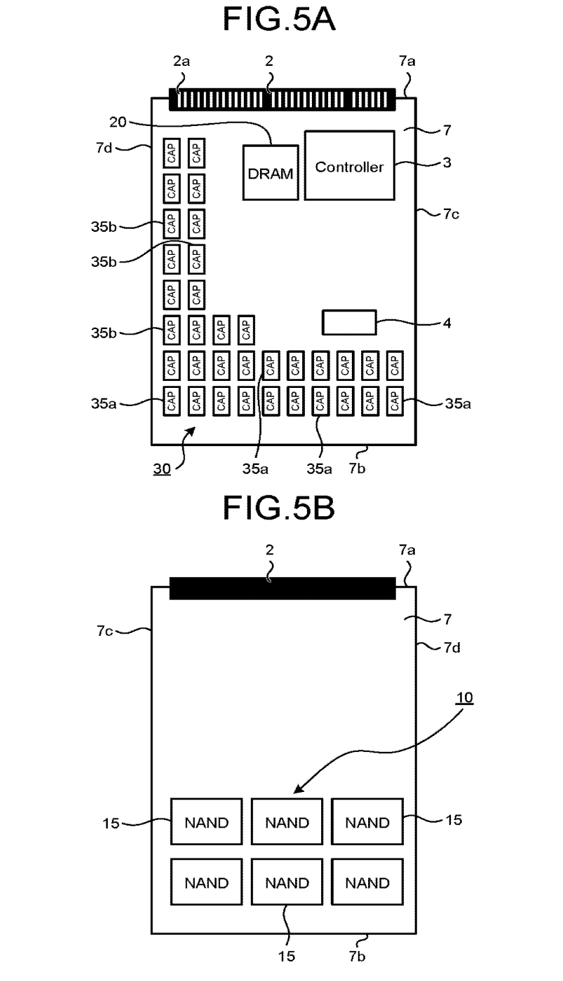

FIGS. 5A and 5B are plan views that illustrate an example of the arrangement of components of a memory system 100 according to a third embodiment. FIG. 5A illustrates the front face of a substrate 7, and FIG. 5B illustrates the rear face of the substrate 7. As illustrated in FIG. 5A, on the front face of the substrate 7, a controller 3, a DRAM 20, a plurality of chip capacitors 35a and 35b configuring a backup power supply 30, and a power supply circuit 4 are mounted. In addition, as illustrated in FIG. 5B, on the rear face of the substrate 7, a plurality of NAND packages 15 configuring a NAND memory 10 are mounted.

The plurality of chip capacitors 35a and 35b are arranged on the front face of the substrate 7 in the shape of “L” when seen from a side 7b in a direction from the side 7b to a side 7a. The plurality of chip capacitors 35a and 35b are disposed in a concentrated manner along sides 7b and 7d but are not disposed in a concentrated manner along a side 7c. In other words, the backup power supply 30 includes chip capacitors 35a disposed along the side 7b and chip capacitors 35b disposed along the side 7d. The power supply circuit 4 is disposed near the backup power supply 30.

The controller 3 is disposed on the front face of the substrate 7 near the connector 2. The controller 3 is disposed to be shifted from the center position of the side 7a in the direction of the side 7c. In other words, the center of the controller 3 is disposed between the center position (midpoint) of the side 7a (a center line of the sides 7c and 7d) and the side 7c. In this way, the plurality of chip capacitors 35a and 35b and the controller 3 are disposed to be separate from each other. Accordingly, the thermal deterioration of the chip capacitors 35a and 35b can be minimized.

The DRAM 20 is disposed between the controller 3 and the side 7d so as to be adjacent to the controller 3. Some of the chip capacitors 35b and the DRAM 20 are disposed between the controller 3 and the side 7d. It is preferable that a space between the chip capacitor 35b and the DRAM 20 is larger than a space between the DRAM 20 and the controller 3.

As illustrated in FIG. 5B, the NAND memory 10 is disposed in a concentrated manner along the side 7b on the rear face of the substrate 7. In addition, the NAND memory 10, similar to the backup power supply 30, is disposed to be separate from the controller 3. Accordingly, the thermal influence of the controller 3 on the NAND memory 10 can be minimized.

In this way, according to the third embodiment, the plurality of the chip capacitors 35a and 35b and the NAND memory 10 are disposed to be separate from the controller 3, and the adverse thermal influence of the controller 3 on the chip capacitors 35a and 35b and the NAND memory 10 can be minimized.

In addition, in the third embodiment, it may be configured such that the plurality of NAND packages 15 are disposed on the front face of the substrate 7, and the controller 3, the DRAM 20, the backup power supply 30, and the power supply circuit 4 are disposed on the rear face of the substrate 7.

### Fourth Embodiment

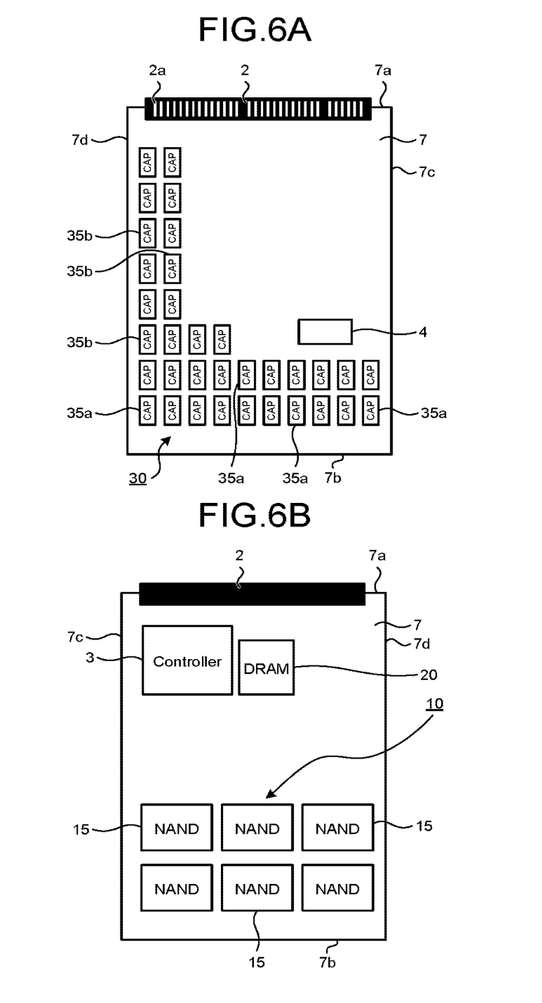

FIGS. 6A and 6B are plan views that illustrate an example of the arrangement of components of a memory system 100 according to a fourth embodiment. FIG. 6A illustrates the front face of a substrate 7, and FIG. 6B illustrates the rear face of the substrate 7. As illustrated in FIG. 6A, on the front face of the substrate 7, a plurality of chip capacitors 35a and 35b configuring a backup power supply 30 and a power supply circuit 4 are mounted. In addition, as illustrated in FIG. 6B, on the rear face of the substrate 7, a controller 3, a DRAM 20, a plurality of NAND packages 15 configuring a NAND memory 10 are mounted.

The plurality of chip capacitors 35a and 35b are disposed on the front face of the substrate 7 in the shape of “L” when seen from a side 7b in a direction from the side 7b to a side 7a. The plurality of chip capacitors 35a and 35b are disposed in a concentrated manner along sides 7b and 7d but are not disposed in a concentrated manner along a side 7c. In other words, the backup power supply 30 includes chip capacitors 35a disposed along the side 7b and chip capacitors 35b disposed along the side 7d. The power supply circuit 4 is disposed near the backup power supply 30.

The controller 3 is disposed on the rear face of the substrate 7 near the connector 2. The controller 3 is disposed to be shifted from the center position of the side 7a in the direction of the side 7c. In other words, the center of the controller 3 is disposed between the center position (midpoint) of the side 7a (a center line of the sides 7c and 7d) and the side 7c. In this way, the plurality of chip capacitors 35a and 35b and the controller 3 are disposed to be separate from each other. Accordingly, the thermal deterioration of the chip capacitors 35a and 35b can be minimized.

The DRAM 20 is disposed on the rear face of the substrate 7, and is disposed between the controller 3 and the side 7d so as to be adjacent to the controller 3. Some of the chip capacitors 35b and the DRAM 20 are disposed between the controller 3 and the side 7d. It is preferable that a space between the chip capacitor 35b and the DRAM 20 is larger than a space between the DRAM 20 and the controller 3.

The NAND memory 10 is disposed in a concentrated manner along the side 7b on the rear face of the substrate 7. In addition, the NAND memory 10, similar to the backup power supply 30, is disposed to be separate from the controller 3. Accordingly, the thermal influence of the controller 3 on the NAND memory 10 can be minimized.

In this way, according to the fourth embodiment, the plurality of the chip capacitors 35a and 35b and the NAND memory 10 are disposed to be separate from the controller 3, and the adverse thermal influence of the controller 3 on the chip capacitors 35a and 35b and the NAND memory 10 can be minimized.

In addition, in the fourth embodiment, it may be configured such that the controller 3, the DRAM 20, and the plurality of NAND packages 15 are disposed on the front face of the substrate 7, and the backup power supply 30 and the power supply circuit 4 are disposed on the rear face of the substrate 7.

### Fifth Embodiment

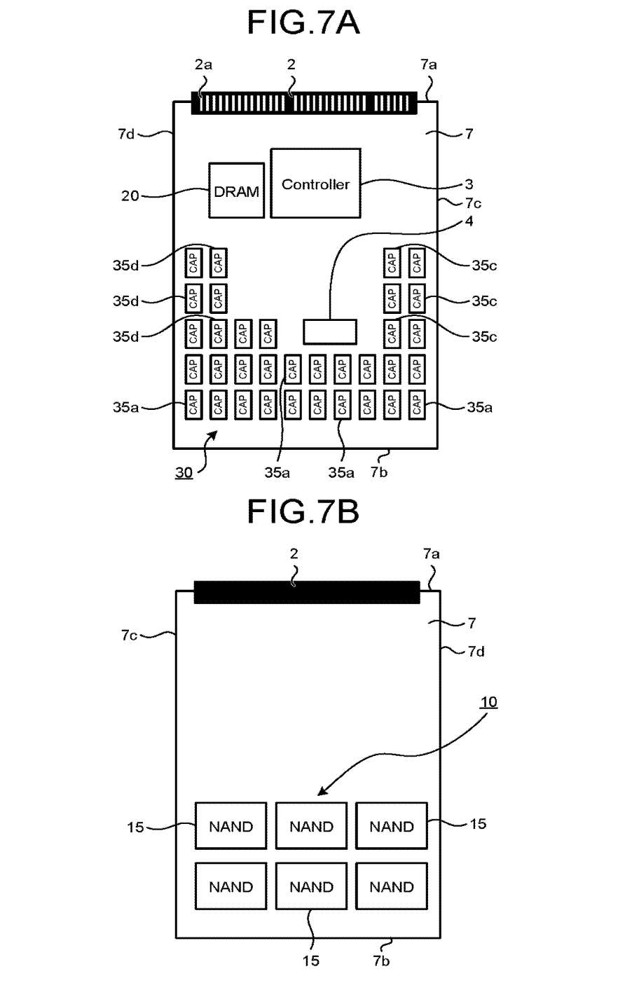

FIGS. 7A and 7B are plan views that illustrate an example of the arrangement of components of a memory system 100 according to a fifth embodiment. FIG. 7A illustrates the front face of a substrate 7, and FIG. 7B illustrates the rear face of the substrate 7. As illustrated in FIG. 7A, on the front face of the substrate 7, a controller 3, a DRAM 20, a plurality of chip capacitors 35a, 35c, and 35d configuring a backup power supply 30, and a power supply circuit 4 are mounted. In addition, as illustrated in FIG. 7B, on the rear face of the substrate 7, a plurality of NAND packages 15 configuring a NAND memory 10 are mounted.

The controller 3 is disposed on the front face of the substrate 7 near the connector 2. The controller 3 is disposed such that the center of the controller 3 is located at an approximately center position of a side 7a. The DRAM 20 is disposed between the controller 3 and a side 7d.

The plurality of chip capacitors 35a, 35c, and 35d are disposed on the front face of the substrate 7 in the shape of “C” when seen from a side 7c in a direction from the side 7c to the side 7d. In other words, the backup power supply 30 includes the chip capacitors 35a disposed along a side 7b, the chip capacitors 35c disposed along the side 7c, and the chip capacitors 35d disposed along the side 7d. In this way, the chip capacitors 35a, 35c, and 35d are disposed along the sides 7b, 7c, and 7d in a concentrated manner. The chip capacitors 35c disposed along the side 7c and the chip capacitors 35d disposed along the side 7d are disposed at positions near the side 7b but are not disposed at positions near the side 7a. In other words, there is no chip capacitor 35d between the DRAM 20 and the side 7d, and there is no chip capacitor 35c between the controller 3 and the side 7c.

The power supply circuit 4 is disposed near the backup power supply 30. In the case illustrated in FIGS. 7A and 7B, the power supply circuit 4 is disposed between the chip capacitors 35c and the chip capacitors 35d. Between the power supply circuit 4 and the controller 3, of the chip capacitors 35c and the chip capacitors 35d are not located. In this way, a plurality of the chip capacitors 35a, 35c, and 35d are disposed to be separate from the controller 3. Accordingly, thermal deterioration of the chip capacitors 35a, 35c, and 35d can be minimized.

The NAND memory 10 is disposed in a concentrated manner along the side 7b on the rear face of the substrate 7. The NAND memory 10, similar to the backup power supply 30, is disposed to be separate from the controller 3. Accordingly, the thermal influence of the controller 3 on the NAND memory 10 can be minimized.

In this way, according to the fifth embodiment, the plurality of the chip capacitors 35a, 35c, and 35d and the NAND memory 10 are disposed to be separate from the controller 3, and the adverse thermal influence of the controller 3 on the chip capacitors 35a, 35c, and 35d and the NAND memory 10 can be minimized.

In addition, in the fifth embodiment, it may be configured such that the plurality of NAND packages 15 are disposed on the front face of the substrate 7, and the controller 3, the DRAM 20, the backup power supply 30, and the power supply circuit 4 are disposed on the rear face of the substrate 7.

### Sixth Embodiment

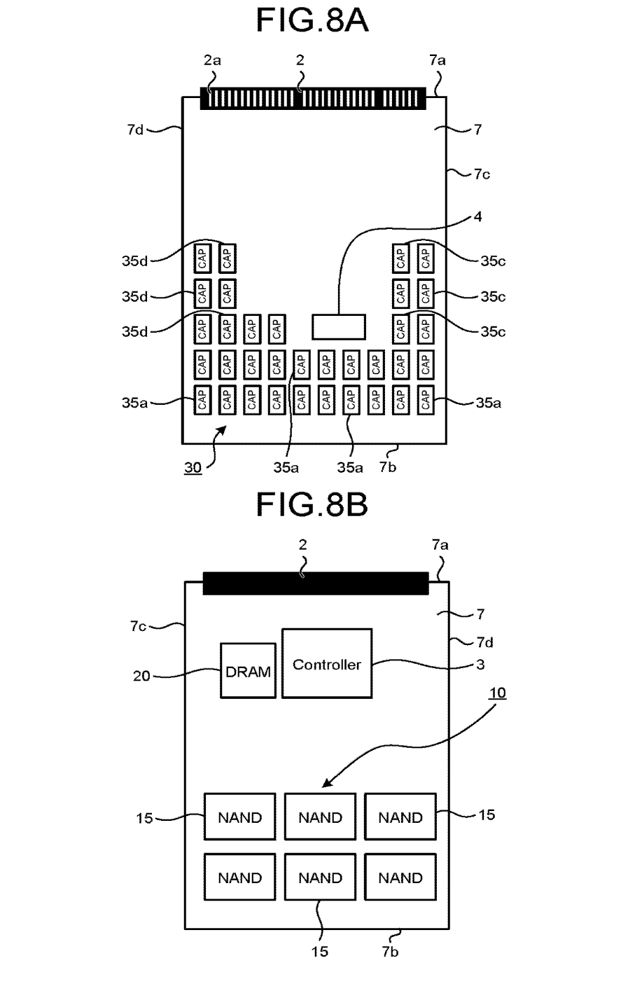

FIGS. 8A and 8B are plan views that illustrate an example of the arrangement of components of a memory system 100 according to a sixth embodiment. FIG. 8A illustrates the front face of a substrate 7, and FIG. 8B illustrates the rear face of the substrate 7. As illustrated in FIG. 8A, on the front face of the substrate 7, a plurality of chip capacitors 35a, 35c, and 35d configuring a backup power supply 30 and a power supply circuit 4 are mounted. In addition, as illustrated in FIG. 7B, on the rear face of the substrate 7, a controller 3, a DRAM 20, and a plurality of NAND packages 15 configuring a NAND memory 10 are mounted.

The controller 3 is disposed on the rear face of the substrate 7 near the connector 2. The controller 3 is disposed such that the center of the controller 3 is located at an approximately center position of a side 7a. The DRAM 20 is disposed between the controller 3 and a side 7d.

The plurality of chip capacitors 35a, 35c, and 35d are disposed on the front face of the substrate 7 in the shape of “C” when seen from a side 7c in a direction from the side 7c to the side 7d. In other words, the backup power supply 30 includes the chip capacitors 35a disposed along a side 7b, the chip capacitors 35c disposed along the side 7c, and the chip capacitors 35d disposed along the side 7d. In this way, the chip capacitors 35a, 35c, and 35d are disposed along the sides 7b, 7c, and 7d in a concentrated manner. The chip capacitors 35 disposed along the side 7c and the chip capacitors 35 disposed along the side 7d are disposed at positions near the side 7b but are not disposed at positions near the side 7a. In other words, there is no chip capacitor 35c between the DRAM 20 and the side 7c, and there is no chip capacitor 35d between the controller 3 and the side 7d.

The power supply circuit 4 is disposed near the backup power supply 30. In the case illustrated in FIGS. 8A and 8B, the power supply circuit 4 is disposed between the chip capacitors 35c and the chip capacitors 35d. Between the power supply circuit 4 and the controller 3, the chip capacitor 35c and the chip capacitors 35d are not located. In this way, a plurality of the chip capacitors 35a, 35c, and 35d are disposed to be separate from the controller 3. Accordingly, thermal deterioration of the chip capacitors 35a, 35c, and 35d can be minimized.

The NAND memory 10 is disposed in a concentrated manner along the side 7b on the rear face of the substrate 7. The NAND memory 10, similar to the backup power supply 30, is disposed to be separate from the controller 3. Accordingly, the thermal influence of the controller 3 on the NAND memory 10 can be minimized.

In this way, according to the sixth embodiment, the plurality of the chip capacitors 35a, 35c, and 35d and the NAND memory 10 are disposed to be separate from the controller 3, and the adverse thermal influence of the controller 3 on the chip capacitors 35a, 35c, and 35d and the NAND memory 10 can be minimized.

In addition, in the sixth embodiment, it may be configured such that the controller 3, the DRAM 20, and the plurality of NAND packages 15 are disposed on the front face of the substrate 7, and the backup power supply 30 and the power supply circuit 4 are disposed on the rear face of the substrate 7.

In addition, in the first to sixth embodiments, while the arrangement of the components of the memory system 100 housed in the casing 40 having a size of 1.8 inches has been described, the arrangement of the components illustrated in the first to sixth embodiments may be applied to a memory system house in a casing having another size.

### Seventh Embodiment

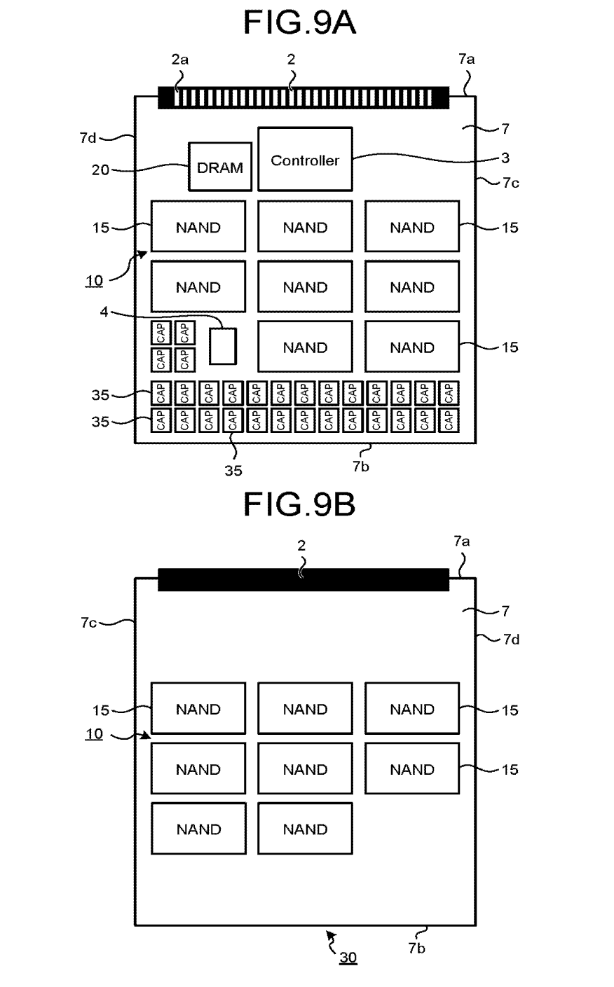

FIGS. 9A and 9B are plan views that illustrate an example of the arrangement of components of a memory system 100 according to a seventh embodiment. FIG. 9A illustrates the front face of a substrate 7, and FIG. 9B illustrates the rear face of the substrate 7. The seventh embodiment is the memory system 100 that is housed in a casing having a size of 2.5 inches and a height of 7 mm.

As illustrated in FIG. 9A, on the front face of the substrate 7, a controller 3, a DRAM 20, and a plurality of NAND packages 15 configuring a NAND memory 10 are mounted. In addition, as illustrated in FIG. 9B, on the rear face of the substrate 7, a plurality of NAND packages 15 configuring a NAND memory 10, a plurality of chip capacitors 35 configuring a backup power supply 30, and a power supply circuit 4 are mounted. In the seventh embodiment, the NAND packages 15 are disposed on the front face and the rear face of the substrate 7.

The controller 3 is disposed on the front face of the substrate 7 near the connector 2. The DRAM 20 is disposed between the controller 3 and a side 7d.

The plurality of chip capacitors 35 are disposed on the rear face of the substrate 7 along a side 7b. The power supply circuit 4 is disposed near the backup power supply 30. In this way, the plurality of chip capacitors 35 are disposed to be separate from the controller 3. Accordingly, thermal deterioration of the chip capacitors 35 can be minimized.

The NAND packages 15 disposed on the front face of the substrate 7 are disposed between the controller 3 and the backup power supply 30. The NAND packages 15 disposed on the rear face of the substrate 7 are disposed not right below the controller 3 but between the controller 3 and the backup power supply 30. It is preferable that the NAND package 15 is disposed along the side 7b so as to secure a space from the controller 3.

In this way, according to the seventh embodiment, the plurality of chip capacitors 35 are disposed to be separate from the controller 3, and the adverse thermal influence of the controller 3 on the chip capacitors 35 can be minimized.

In addition, according to the seventh embodiment, it may be configured such that the plurality of NAND packages 15 are disposed on the front face of the substrate 7, and the controller 3, the DRAM 20, the backup power supply 30, the power supply circuit 4, and the plurality of NAND packages 15 are disposed on the rear face of the substrate 7.

### Eighth Embodiment

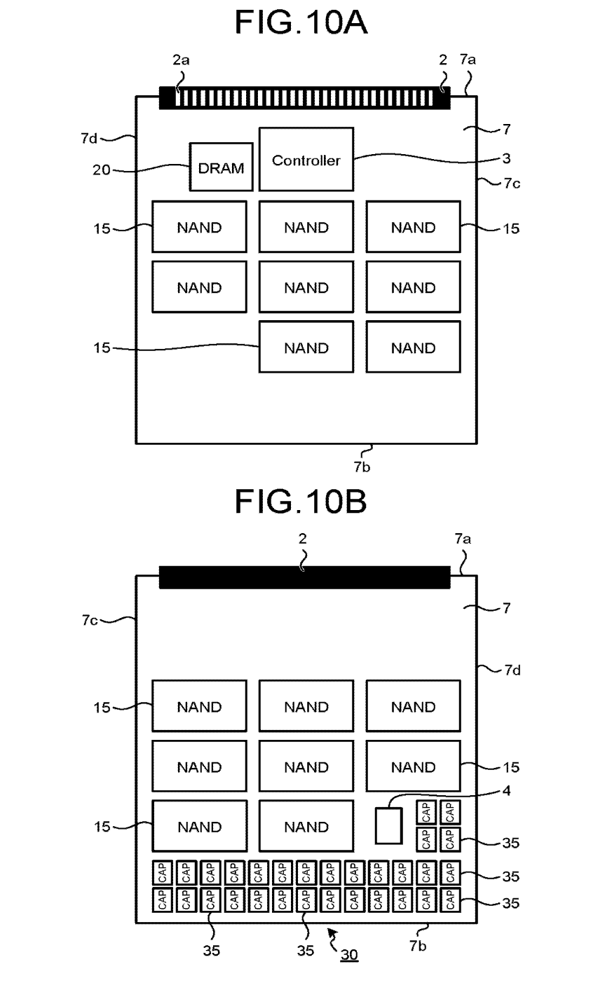

FIGS. 10A and 10B are plan views that illustrate an example of the arrangement of components of a memory system 100 according to an eighth embodiment. FIG. 10A illustrates the front face of a substrate 7, and FIG. 10B illustrates the rear face of the substrate 7. The eighth embodiment is the memory system 100 that is housed in a casing having a size of 2.5 inches and a height of 7 mm.

As illustrated in FIG. 10A, on the front face of the substrate 7, a controller 3, a DRAM 20, a plurality of NAND packages 15 configuring a NAND memory 10, a plurality of chip capacitors 35 configuring a backup power supply 30, and a power supply circuit 4 are mounted. In addition, as illustrated in FIG. 10B, on the rear face of the substrate 7, a plurality of NAND packages 15 configuring a NAND memory 10 are disposed. In the eighth embodiment, the NAND packages 15 are disposed on the front face and the rear face of the substrate 7.

The controller 3 is disposed on the front face of the substrate 7 near the connector 2. The DRAM 20 is disposed between the controller 3 and a side 7d.

The plurality of NAND packages 15 are disposed on the front face of the substrate 7. It is preferable that the NAND packages 15 are disposed along a side 7b so as to secure a space from the controller 3.

The plurality of chip capacitors 35 are disposed on the rear face of the substrate 7 along the side 7b. The power supply circuit 4 is disposed near the backup power supply 30. In this way, the plurality of chip capacitors 35 are disposed to be separate from the controller 3. Accordingly, thermal deterioration of the chip capacitors 35 can be minimized.

The NAND packages 15 disposed on the rear face of the substrate 7 are disposed not right below the controller 3 but between the controller 3 and the backup power supply 30. Accordingly, the thermal influence of the controller 3 on the NAND memory 10 can be minimized.

In this way, according to the eighth embodiment, the plurality of chip capacitors 35 are disposed to be separate from the controller 3, and the adverse thermal influence of the controller 3 on the chip capacitors 35 can be minimized.

In addition, according to the eighth embodiment, it may be configured such that the backup power supply 30, the power supply circuit 4, and the plurality of NAND packages 15 are disposed on the front face of the substrate 7, and the controller 3, the DRAM 20, and the plurality of NAND packages 15 are disposed on the rear face of the substrate 7.

In the description herein, a first face of a substrate represents one of the front face and the rear face of the substrate. In a case where the first face of the substrate is assumed to be the front face, the second face of the substrate represents the rear face of the substrate. On the other hand, in a case where the first face of the substrate is assumed to be the rear face, the second face of the substrate represents the front face of the substrate.

In addition, it is apparent that the arrangements of the components illustrated in the first to eighth embodiments described above may be applied also to a memory system having a substrate size other than the 1.8-inch standard and the 2.5-inch standard.

### Ninth Embodiment

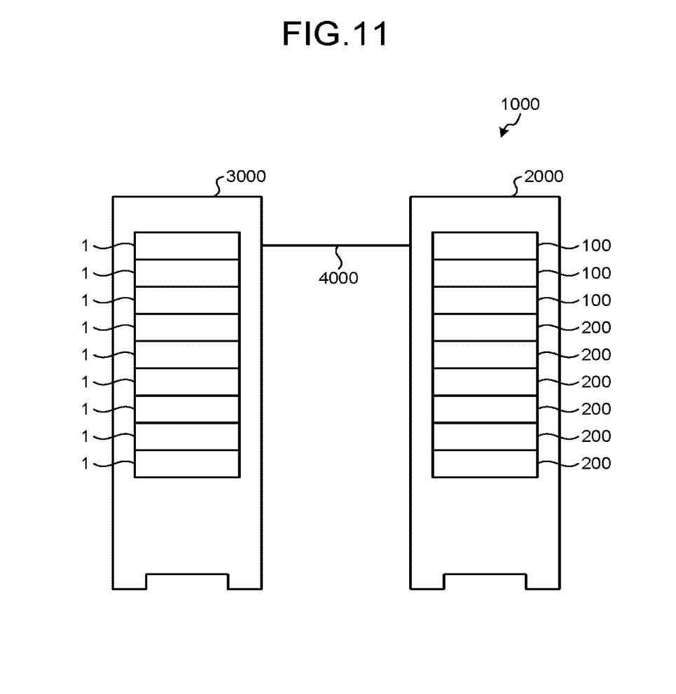

FIG. 11 is a diagram that illustrates an example of mounting of the memory system 100. The memory system 100, for example, is mounted in a server system 1000. The server system 1000 is configured by connecting a disk array 2000 and a rack mount server 3000 using a communication interface 4000. As the standard of the communication interface 4000, an arbitrary standard may be employed. The rack mount server 3000 is configured by mounting one or more hosts 1 in a server rack. A plurality of the hosts 1 can access the disk array 2000 through the communication interface 4000.

In addition, the disk array 2000 is configured by mounting one or more memory systems 100 and one or more hard disk units 200 in the server rack. Each memory system 100 can execute a command transmitted from each host 1. In addition, each memory system 100 has a configuration that employs one of the first to eighth embodiments.

Furthermore, in the disk array 2000, for example, each memory system 100 may be used as a cache of one or more hard disk units 200. In the disk array 2000, a storage controller unit building a RAID in one or more hard disk units 200 may be mounted.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a substrate;
a connector disposed at a first side of the substrate;
a controller mounted on a first face of the substrate and disposed near the connector;
a plurality of first capacitors mounted on the first face of the substrate and disposed along a second side opposing the first side; and
a plurality of first memory packages mounted on a second face of the substrate, each of the memory packages including a non-volatile semiconductor memory.

2. The semiconductor memory device according to claim 1, wherein the plurality of first memory packages are disposed along the second side.

3. The semiconductor memory device according to claim 2, wherein the plurality of first capacitors and the plurality of memory packages are disposed between the second side and a center line of the first and the second sides, and the controller is disposed between the first side and the center line of the first and the second sides.

4. The semiconductor memory device according to claim 2, wherein a center of the controller is located between a first line and a third side intersecting with the first side, the first line being orthogonal to the first side, the first line passing through a midpoint of the first side, and
the semiconductor memory device further comprising a plurality of second capacitors mounted on the first face of the substrate, the second capacitors being disposed along a fourth side but not being disposed along the third side, the forth side opposing the third side.

5. The semiconductor memory device according to claim 4, further comprising a volatile memory,
wherein a part of the plurality of second capacitors and the volatile memory are located between a first side of the controller and the fourth side, the first side of the controller opposing the fourth side,
a space between the part of the plurality of second capacitors and the volatile memory is larger than a space between the volatile memory and the controller.

6. The semiconductor memory device according to claim 2, further comprising a plurality of third capacitors and a plurality of fourth capacitors mounted on the first face of the substrate, the third capacitors being disposed along a third side intersecting with the first side, the fourth capacitors being disposed along a fourth side opposing the third side.

7. The semiconductor memory device according to claim 6, further comprising a volatile memory, wherein
the volatile memory is located between a first side of the controller opposing the fourth side and the fourth side,
the fourth capacitor is not located between the volatile memory and the fourth side.

8. The semiconductor memory device according to claim 7, wherein the third capacitors are not located between a second side of the controller opposing the third side and the third side.

9. The semiconductor memory device according to claim 8, further comprising a power supply circuit, wherein
the power supply circuit is located between the plurality of third capacitors and the plurality of fourth capacitors,
none of the plurality of third capacitors and the plurality of fourth capacitors is located between the power supply circuit and the controller.

10. The semiconductor memory device according to claim 1, further comprising one or a plurality of second memory packages mounted on the first face of the substrate, the second memory packages including a non-volatile semiconductor memory, the second memory packages being disposed between the controller and the first capacitors.

11. A semiconductor memory device comprising:
a substrate;
a connector disposed at a first side of the substrate;
a controller mounted on a first face of the substrate and disposed near the connector;
a plurality of first memory packages mounted on the first face of the substrate, each of the memory packages including a non-volatile semiconductor memory; and
a plurality of first capacitors mounted on a second of the substrate and disposed along a second side opposing the first side.

12. The semiconductor memory device according to claim 11, wherein the plurality of first memory packages is disposed along the second side.

13. The semiconductor memory device according to claim 12, wherein
the plurality of first capacitors and the plurality of memory packages are disposed between the second side and a center line of the first and the second sides, and the controller is disposed between the first side and the center line of the first and the second sides.

14. The semiconductor memory device according to claim 12, wherein a center of the controller is located between a first line and a third side intersecting with the first side, the first line being orthogonal to the first side, the first line passing through a midpoint of the first side, and
the semiconductor memory device further comprising a plurality of second capacitors mounted on the second face of the substrate, the second capacitors being disposed along a fourth side but not being disposed along the third side, the fourth side opposing the third side.

15. The semiconductor memory device according to claim 14, further comprising a volatile memory,
wherein a part of the plurality of second capacitors and the volatile memory are located between a first side of the controller and the fourth side, the first side of the controller opposing the fourth side,
a space between the part of the plurality of second capacitors and the volatile memory is larger than a space between the volatile memory and the controller.

16. The semiconductor memory device according to claim 12, further comprising a plurality of third capacitors and a plurality of fourth capacitors mounted on the second face of the substrate, the third capacitors being disposed along a third side intersecting with the first side, the fourth capacitors being disposed along a fourth side opposing the third side.

17. The semiconductor memory device according to claim 16, further comprising a volatile memory, wherein
the volatile memory is located between a first side of the controller and the fourth side, the first side of the controller opposing the fourth side,
the fourth capacitor is not located between the volatile memory and the fourth side.

18. The semiconductor memory device according to claim 17, wherein the third capacitors are not located between a second side of the controller and the third side, the second side of the controller opposing the third side.

19. The semiconductor memory device according to claim 18, further comprising a power supply circuit, wherein
the power supply circuit is located between the plurality of third capacitors and the plurality of fourth capacitors,
none of the plurality of third capacitors and the plurality of fourth capacitors is located between the power supply circuit and the controller.

20. The semiconductor memory device according to claim 11, further comprising one or a plurality of second memory packages mounted on the second face of the substrate, each of the second memory packages including a non-volatile semiconductor memory, the second memory packages being disposed between the controller and the first capacitors.
